(19) United States
(12) Patent Application Publication
(10) Pub. No.: US 2024/0087883 A1
(43) Pub. Date: Mar. 14, 2024

(54) METHOD FOR FORMING SILICON-CONTAINING FILM AND FILM FORMING APPARATUS

(71) Applicant: Tokyo Electron Limited, Tokyo (JP)

(72) Inventors: Nobuo MATSUKI, Yamanashi (JP); Yoshinori MORISADA, Yamanashi (JP); Daisuke OBA, Yamanashi (JP)

(21) Appl. No.: 18/271,898

(22) PCT Filed: Jan. 11, 2022
(86) PCT No.: PCT/JP2022/000542

§ 371 Date: Jul. 12, 2023

(30) Foreign Application Priority Data
Jan. 20, 2021 (JP) 2021-007404

(51) Int. Cl. H01L 21/02

(52) U.S. Cl. CPC H01L 21/02211; H01L 21/0217; H01L 21/02274

(57) ABSTRACT

A method for forming a silicon-containing film in a recess formed on a surface of a substrate, the method includes: (a) forming a flowable film in the recess by exposing the substrate, which is adjusted to a first temperature, to plasma generated from a processing gas including a halogen-containing silane: and (b) curing the flowable film by thermally processing the substrate at a second temperature higher than the first temperature.

This is a National Phase Application filed under 35 U.S.C. 371 as a national stage of PCT/JP2022/000542, filed Jan. 11, 2022, an application claiming the benefit of Japanese Application No. 2021-007404, filed Jan. 20, 2021, the content of each of which is hereby incorporated by reference in its entirety.

### TECHNICAL FIELD

The present disclosure relates to a method for forming a silicon-containing film and a film forming apparatus.

### BACKGROUND

In a semiconductor manufacturing process, it is required to embed a film in a recess with a high aspect ratio, without voids or seams, to accompany miniaturization of a structure.

As an example of the embedding process, a technique of embedding silicon in a contact hole by thermal CVD is known (see, e.g., Patent Document 1). As another example of the embedding process, a technique of forming a flowable film by PECVD, processing the flowable film to form a SiX film (where X=C, O, or N), and curing the flowable film or the SiX film to solidify the film is known (see, e.g., Patent Document 2). As still another example of the embedding process, a technique of supplying reaction gases, including one or more of SiH₄, Si₂H₆, Si₃H₈, and Si₄H₁₀ and a diluent gas or carrier gas, to a surface of a pretreated substrate to deposit a flowable silicon layer is known (see, e.g., Patent Document 3).

### PRIOR ART DOCUMENTS

### Patent Documents

Patent Document 1: Japanese Laid-Open Publication No. 1994-005540
Patent Document 2: Japanese National Publication of International Patent Application No. 2020-516079
Patent Document 3: Japanese National Publication of International Patent Application No. 2020-517097

The present disclosure provides a technique capable of forming a silicon-containing film in a recess with a high aspect ratio by bottom-up growth.

### SUMMARY

A method for forming a silicon-containing film according to an aspect of the present disclosure is a method of forming a silicon-containing film in a recess formed on a surface of a substrate, the method including (a) forming a flowable film in the recess by exposing the substrate, which is adjusted to a first temperature, to plasma generated from a processing gas including a halogen-containing silane, and (b) curing the flowable film by thermally processing the substrate at a second temperature higher than the first temperature.

According to the present disclosure, it is possible to form a silicon-containing film in a recess with a high aspect ratio by bottom-up growth.

### BRIEF DESCRIPTION OF DRAWINGS

FIG. 1 is a flowchart illustrating an example of a method of forming a silicon-containing film according to an embodiment.

FIG. 2A is a diagram illustrating a reaction mechanism of the method of forming a silicon-containing film according to the embodiment.

FIG. 2B is a diagram illustrating a reaction mechanism of the method of forming a silicon-containing film according to the embodiment.

FIG. 3 is a diagram illustrating a reaction mechanism of the method of forming a silicon-containing film according to the embodiment.

FIG. 4 is a diagram illustrating a reaction mechanism of the method of forming a silicon-containing film according to the embodiment.

FIG. 5 is a diagram illustrating a reaction mechanism of the method of forming a silicon-containing film according to the embodiment.

FIG. 6 is a diagram illustrating the embedding characteristics of a silicon-containing film according to the embodiment.

FIG. 7 is a diagram illustrating the embedding characteristics of the silicon-containing film according to the embodiment.

FIG. 8A is a diagram illustrating embedding characteristics of a silicon-containing film in a method of the related art.

FIG. 8B is a diagram illustrating the embedding characteristics of the silicon-containing film in the method of the related art.

FIG. 9A is a diagram illustrating the embedding characteristics of the silicon-containing film in the method of the related art.

FIG. 9B is a diagram illustrating the embedding characteristics of the silicon-containing film in the method of the related art.

FIG. 9C is a diagram illustrating the embedding characteristics of the silicon-containing film in the method of the related art.

FIG. 10 is a diagram illustrating an example of a film forming apparatus that performs the method of forming a silicon-containing film according to the embodiment.

### DETAILED DESCRIPTION

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions thereof will be omitted.

[Method of Forming Silicon-Containing Film]

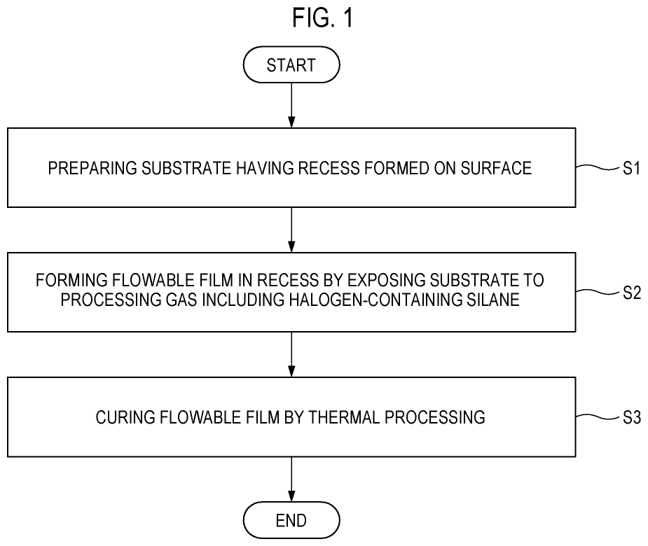

An example of a method of forming a silicon-containing film according to an embodiment will be described with reference to FIGS. 1 to 9C. In the following, a method of embedding a silicon-containing film in a recess formed on a surface of a substrate will be described by way of example.

As illustrated in FIG. 1, the method of forming a silicon-containing film according to the embodiment includes step S1 of preparing a substrate, step S2 of forming a flowable film, and step S3 of curing the flowable film.

In step S1 of preparing the substrate, the substrate having a recess formed on a surface thereof is prepared. The substrate may be, for example, a semiconductor wafer. The recess may be, for example, a trench or a hole.

In step S2 of forming the flowable film, the flowable film is formed in the recess by exposing the substrate, which is adjusted to a first temperature, to plasma generated from a processing gas including a halogen-containing silane. The halogen-containing silane may be, for example, one or a plurality of asymmetric silanes represented by SiₙHₓZ₂ₙ₊₂₋ₓ (where Z is F, Cl, Br or I, n is a natural number of 1 or more, and x is 1 to 2n+2−1). The first temperature is a temperature at which the flowable film is formed in the recess when the substrate is exposed to plasma generated from the processing gas including the halogen-containing silane. The first temperature may be, for example, 80 degrees C. or lower. The plasma may be, for example, capacitively coupled plasma, inductively coupled plasma, or microwave plasma.

Further, in a case of embedding in an intricate structure, a halogen-containing silane, which has a small number of Si bonds, a low molecular weight and high fluidity, is desired. Thus, since the halogen-containing silane infiltrates deep into an intricate structure by capillary action, a silicon-containing film may be embedded in the intricate structure without voids (gaps) or seams (joints). Examples of the intricate structure may include a recess with a high aspect ratio (e.g., a trench or hole having an aspect ratio greater than 20) and a recess having an internally widening structure. Examples of the halogen-containing silane, which has a small number of Si bonds, a low molecular weight, and high fluidity, may include SiHₓZ₄₋ₓ(where Z is F, Cl, Br or I, and x is 1, 2 or 3), Si₂HₓZ₆₋ₓ (where Z is F, Cl, Br or I, and x is 1, 2, 3, 4 or 5), and combinations thereof. A specific example of the halogen-containing silane may include dichlorosilane (DCS: SiH₂Cl₂).

Further, in the halogen-containing silane, the polarization of silicon increases since hydrogen (H) and halogen are bonded to silicon (Si) and since the electronegativity of halogen greatly differs from that of hydrogen (the electronegativity of halogen being greater than that of hydrogen). When the halogen-containing silane is mixed with a halogen-free silane and they are polymerized with plasma, a Si oligomer containing halogen and hydrogen is efficiently generated, so that the Si oligomer is deposited on a substrate. Therefore, the processing gas may include the halogen-free silane in addition to the halogen-containing silane. The halogen-free silane may be, for example, one or a plurality of gases represented by SiₓH₂₊₂ₓ (where x is a natural number of 1 or more). Specific examples of the halogen-free silane may include monosilane (SiH₄) and disilane (Si₂H₆).

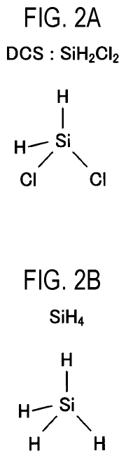

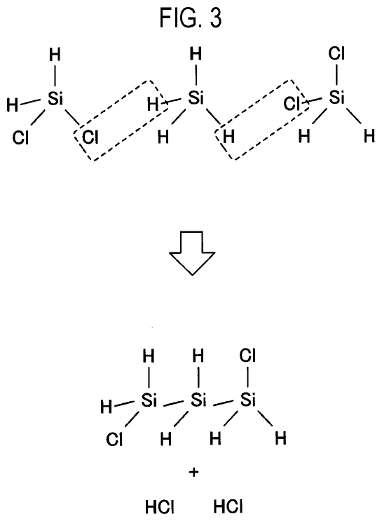

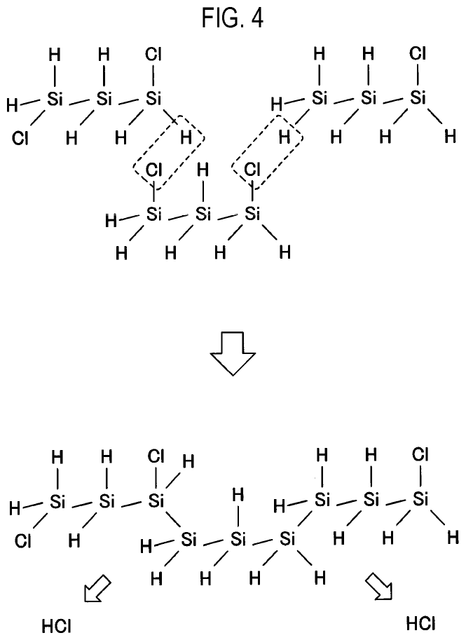

For example, a case of using DCS as the halogen-containing silane (see FIG. 2A) and SiH₄ as the halogen-free silane (see FIG. 2B) will be considered. In this case, as illustrated in FIG. 3, a plasma polymerization takes place between DCS and SiH₄, and then, as illustrated in FIG. 4, a further plasma polymerization takes place between molecules generated by the plasma polymerization, resulting in generation of an oligomer. At this time, due to a condensation reaction of partially added chlorine (Cl) and hydrogen (H), H in the Si—H group and Cl in the Si—Cl group combine and dissociate as HCl, and Si in the Si—H group and Si in the Si—Cl group newly combine. This promotes the growth of a linear oligomer with high fluidity.

Further, the processing gas may include a metal-containing gas. That is, the metal-containing gas may be added to the halogen-containing silane. Thus, a metal silicide may be formed. The metal-containing gas may be a gas containing metal elements such as aluminum (Al), zinc (Zn), and nickel (Ni). A specific example of the metal-containing gas may include an organometallic compound such as trimethylaluminum (TMA).

Further, the processing gas may include a diluent gas. That is, a diluent gas may be added to the halogen-containing silane. Specific examples of the diluent gas may include hydrogen (H₂), helium (He), nitrogen (N₂), argon (Ar), and combinations thereof. Furthermore, a nitrous oxide (N₂O), oxygen (O₂), a carbon dioxide (CO₂), or a carbon monoxide (CO) may be added as an additive gas to the diluent gas.

In step S3 of curing the flowable film, the flowable film is cured by thermally processing the substrate having the flowable film formed in the recess at a second temperature higher than the first temperature, thereby forming a silicon-containing film. At this time, the Si—H group and the Si—Cl group undergo a bonding reaction between a plurality of oligomers constituting the flowable film, causing solidification of the flowable film in a condensation reaction while maintaining the fluidity thereof, so that a non-porous and dense silicon-containing film is formed. The second temperature is a temperature at which the flowable film may be cured. The second temperature may be, for example, 150 degrees C. or higher and 750 degrees C. or lower.

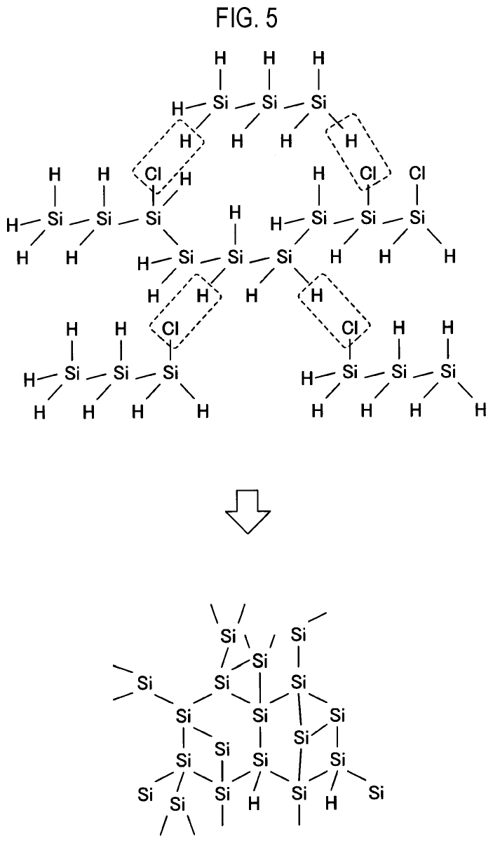

For example, in a case of using DCS as the halogen-containing silane and SiH₄ as the halogen-free silane, as illustrated in FIG. 5, a condensation reaction of Cl and H, which remain bonded without dissociation in step S2 of forming the flowable film, takes place between the plurality of oligomers constituting the flowable film. Further, a dehydrogenative condensation reaction of H and H takes place by a thermal processing between and within the plurality of oligomers constituting the flowable film. As a result, the flowable film is cured to form a silicon-containing film.

Further, from the viewpoint of preventing impurities such as oxygen from entering the silicon-containing film, step S3 of curing the flowable film may be performed without exposing the substrate to the atmosphere after step S2 of forming the flowable film. That is, step S2 of forming the flowable film and step S3 of curing the flowable film may be continuously performed under a vacuum atmosphere.

Further, step S3 of curing the flowable film may be performed within a short time (e.g., within 60 seconds) after step S2 of forming the flowable film. Thus, the flowable film embedded in the recess in step S2 of forming the flowable film may be solidified by the condensation reaction while maintaining the fluidity thereof. As a result, a non-porous and dense film is formed.

Further, in step S3 of curing the flowable film, the substrate may be exposed to plasma generated from H₂ (hereinafter also referred to as “H₂ plasma”). By exposing the substrate to the H₂ plasma, the flowable film may be cured while removing impurities contained in the flowable film. Therefore, the in-film impurity concentration of the silicon-containing film embedded in the recess may be reduced. For example, the H₂ plasma may be generated using RF power having a frequency band (VHF wave) of 100 MHz or more and 1 GHz or less. Further, in step S3 of curing the flowable film, the substrate may be irradiated with ultraviolet rays (UV).

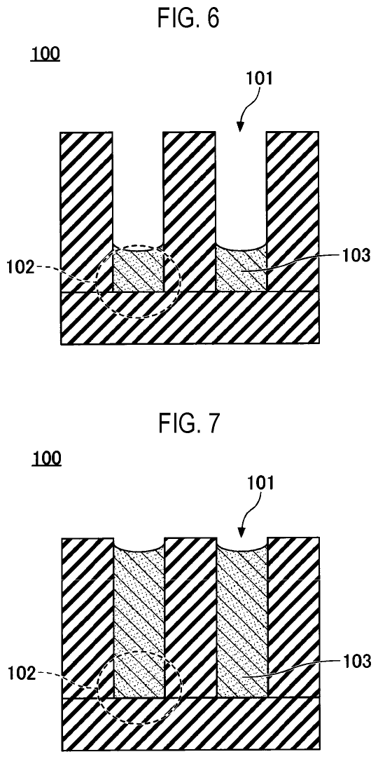

As described above, according to the method of forming the silicon-containing film of the embodiment, the flowable film is formed in the recess by exposing the substrate, which is adjusted to the first temperature, to plasma generated from the processing gas including the halogen-containing silane. The flowable film is then cured by thermally processing the substrate at the second temperature higher than the first temperature. Thus, as illustrated in FIG. 6, a liquid-state oligomer deposited on the substrate 100 infiltrates deep into a narrow structure (recess 101) by capillary action. Then, the fluidity of the flowable film is maintained even in a state where the substrate 100 is thermally processed to solidify the flowable film, so that Si condenses and solidifies on a bottom 102 of the recess 101 by dissociation and condensation of Cl, H, and the like. Therefore, a silicon-containing film 103 may be formed in the recess 101 with a high aspect ratio by bottom-up growth.

Further, according to the method of forming the silicon-containing film of the embodiment, the processing gas used when forming the flowable film includes the halogen-containing silane. Thus, since halogen is contained in the oligomers constituting the flowable film, H may be efficiently removed when the flowable film is solidified by the thermal processing. As a result, a stable silicon-containing film may be formed. On the other hand, if the processing gas used when forming the flowable film does not include the halogen-containing silane, for example, if the processing gas includes only a high-order silane, it is difficult to remove H during solidification of the flowable film by the thermal processing.

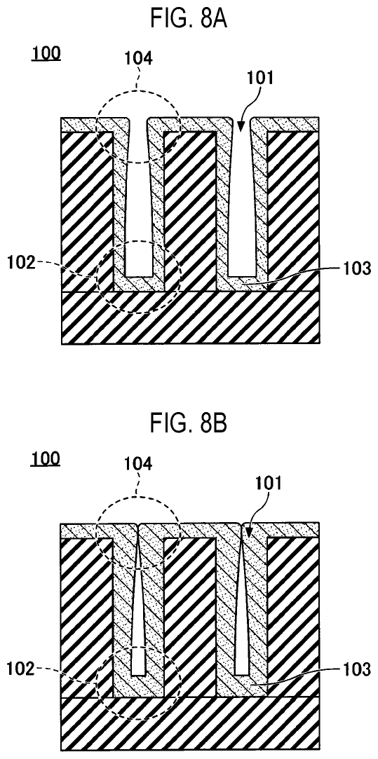

In addition, FIG. 6 illustrates a case where the silicon-containing film 103 is embedded in a part of the recess 101 including the bottom 102 without being completely embedded the recess 101, but the method of forming the silicon-containing film may also be applied to a case where the silicon-containing film 103 is completely embedded in the recess 101. Similarly, even when the silicon-containing film 103 is completely embedded in the recess 101, Si condenses and solidifies in a state where the liquid-state oligomer deposited on the substrate 100 infiltrates deep into the recess 101 by capillary action and the fluidity of the flowable film is maintained. Therefore, the silicon-containing film 103 may be formed in the recess 101 with a high aspect ratio by bottom-up growth, and as illustrated in FIG. 7, the silicon-containing film 103 may be embedded in the recess 101 without voids or seams.

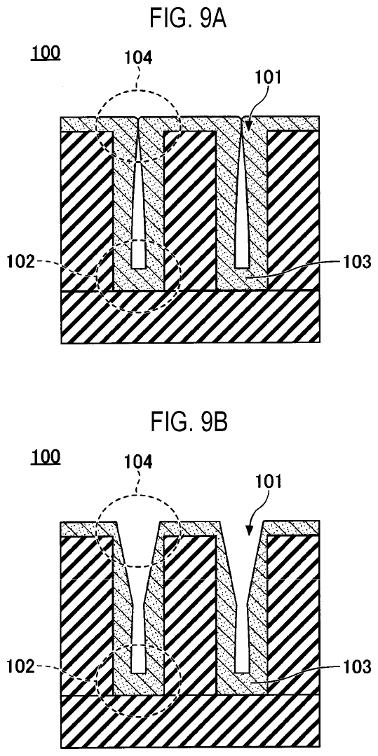

On the other hand, in the techniques in the related art such as thermal CVD and plasma CVD, as illustrated in FIG. 8A, there is a characteristic where the film formation rate at an opening 104 of the recess 101, to which a material is supplied, is faster than the film formation rate at the bottom 102 of the recess 101. Therefore, when embedding in the recess 101 with a high aspect ratio, as illustrated in FIG. 8B, the opening 104 of the recess 101 is blocked before the interior of the recess 101 is filled, which causes voids, resulting in poor embedding.

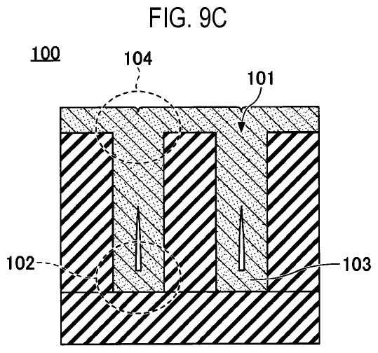

Hence, in the related art, the embedding characteristics are improved by removing the blockage of the opening 104 (see FIG. 9A) by reactive ion etching (RIE) (see FIG. 9B) and forming a film (see FIG. 9C). That is, the embedding characteristics are improved by alternately repeating film formation (deposition) and etching to embed a film in the recess 101. However, even in the method of alternately repeating deposition and etching to embed a film in the recess 101, when embedding a film in a recess with a high aspect ratio or a recess having an internally widening structure, voids remain at the bottom of the recess so as to make it difficult to achieve complete embedding.

[Film Forming Apparatus]

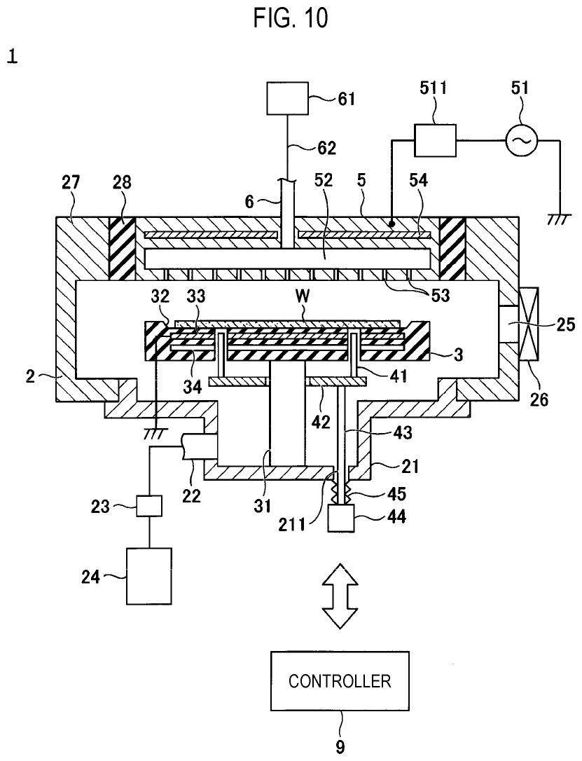

An example of a film forming apparatus (film former) that performs step S2 of forming the flowable film described above will be described with reference to FIG. 10. In addition, a curing apparatus (thermal processor) that performs step S3 of curing the flowable film may have the same configuration as that of the film forming apparatus that performs step S2 of forming the flowable film.

As illustrated in FIG. 10, the film forming apparatus 1 is a device that forms a silicon nitride film on a semiconductor wafer (hereinafter referred to as “wafer W”), which is an example of a substrate, by a chemical vapor deposition (CVD) method using plasma. The film forming apparatus 1 includes a hermetically sealed processing container 2 having a substantially cylindrical shape. An exhaust chamber 21 is provided at a central portion of a bottom wall of the processing container 2.

The exhaust chamber 21 protrudes downwards and has, for example, a substantially cylindrical shape. An exhaust flow path 22 is connected to the exhaust chamber 21, for example, at a side surface of the exhaust chamber 21.

An exhauster 24 is connected to the exhaust flow path 22 via a pressure regulator 23. The pressure regulator 23 includes, for example, a pressure regulating valve such as a butterfly valve. The exhaust flow path 22 is configured to be capable of depressurizing the interior of the processing container 2 by the exhauster 24. A transfer port 25 is provided on a side surface of the processing container 2. The transfer port 25 is configured to be capable of opening and closing by a gate valve 26. The loading/unloading of the wafer W between the interior of the processing container 2 and a transfer chamber (not illustrated) is performed through the transfer port 25.

A stage 3 for holding the wafer W substantially horizontally is provided inside the processing container 2. The stage 3 is formed in a substantially circular shape in a plan view, and is supported by a support member 31. A substantially circular recess 32 is formed on a surface of the stage 3 for placing the wafer W having a diameter of, for example, 300 mm. The recess 32 has an inner diameter slightly larger than the diameter of the wafer W (e.g., by about 1 mm to 4 mm). A depth of the recess 32 is substantially the same as a thickness of the wafer W, for example. The stage 3 is made of a ceramic material such as aluminum nitride (AlN), for example. Further, the stage 3 may be made of a metal material such as nickel (Ni). In addition, instead of the recess 32, a guide ring for guiding the wafer W may be provided on a periphery of the surface of the stage 3.

In the stage 3, for example, a grounded lower electrode 33 is embedded. A temperature adjuster 34 is embedded under the lower electrode 33. The temperature adjuster 34 adjusts, based on a control signal from a controller 9, the wafer W placed on the stage 3 to a set temperature (e.g., a temperature of −50 degrees C. to 80 degrees C., and in a stage used for a thermal processing, for example, a temperature of 150 degrees C. to 750 degrees C.). In a case where the entire stage 3 is made of a metal, the entire stage 3 functions as a lower electrode, and therefore, it is not necessary to embed the lower electrode 33 in the stage 3. The stage 3 is provided with a plurality of (e.g., three) lifting pins 41 for holding and lifting the wafer W placed on the stage 3. A material of the lifting pins 41 may be, for example, ceramics such as alumina (Al₂O₃), quartz, or the like. A lower end of each lifting pin 41 is attached to a support plate 42. The support plate 42 is connected to a lifter 44 provided outside the processing container 2 via a lifting shaft 43.

The lifter 44 is attached, for example, to a lower portion of the exhaust chamber 21. A bellows 45 is provided between the lifter 44 and an opening 211 for the lifting shaft 43 formed in a lower surface of the exhaust chamber 21. The support plate 42 may be shaped to be capable of moving up and down without interfering with the support member 31 of the stage 3. The lifting pins 41 are configured to be capable of moving up and down between the upper side of the surface of the stage 3 and the lower side of the surface of the stage 3 by the lifter 44. In other words, the lifting pins 41 are configured to be capable of protruding from an upper surface of the stage 3.

A gas supplier 5 is provided on a ceiling wall 27 of the processing container 2 with an insulating member 28 interposed therebetween. The gas supplier 5 forms an upper electrode and faces the lower electrode 33. An RF power supply 51 is connected to the gas supplier 5 via a matcher 511. A frequency band of the RF power supply 51 is, for example, 450 kHz to 2.45 GHz. The gas supplier 5 is configured such that an RF electric field is generated between the upper electrode (gas supplier 5) and the lower electrode 33 by supplying RF power from the RF power supply 51 to the upper electrode (gas supplier 5). The gas supplier 5 includes a hollow gas diffusion chamber 52. A large number of holes 53 for dispersing and supplying the processing gas into the processing container 2 are, for example, evenly arranged on a lower surface of the gas diffusion chamber 52. A heater 54 is embedded, for example, above the gas diffusion chamber 52 in the gas supplier 5. The heater 54 is heated to a set temperature upon receiving power from a power supply (not illustrated) based on a control signal from the controller 9.

A gas supply path 6 is provided in the gas diffusion chamber 52. The gas supply path 6 communicates with the gas diffusion chamber 52. A gas source 61 is connected to the upstream side of the gas supply path 6 via a gas line 62. The gas source 61 includes, for example, sources of various processing gases, mass flow controllers, and valves (none of which are illustrated). The various processing gases include gases used in the method of forming the silicon-containing film described above. These various processing gases are introduced into the gas diffusion chamber 52 from the gas source 61 through the gas line 62.

Examples of the various processing gases may include a halogen-containing silane, a halogen-free silane, a metal-containing gas, a diluent gas, and an additive gas. The halogen-containing silane may be, for example, one or a plurality of gases represented by SiₙHₓZ₂ₙ₊₂₋ₓ (where Z is F, Cl, Br or I, n is a natural number of 1 or more, and x is 1 to 2n+2−1). The halogen-free silane may be, for example, one or a plurality of gases represented by SiₓH₂₊₂ₓ (where x is a natural number of 1 or more). The metal-containing gas may be, for example, a gas containing metal elements such as Al, Zn, and Ni. The diluent gas may be, for example, H₂, He, N₂, Ar and combinations thereof. The additive gas may be, for example, N₂O, O₂, CO₂, CO, and combinations thereof.

The film forming apparatus 1 includes the controller 9. The controller 9 is, for example, a computer, and includes a central processing unit (CPU), a random access memory (RAM), a read only memory (ROM), an auxiliary storage device, and the like. The CPU operates based on programs stored in the ROM or the auxiliary storage device to control the operation of the film forming apparatus 1. The controller 9 may be provided inside or outside the film forming apparatus 1. When the controller 9 is provided outside the film forming apparatus 1, the controller 9 may control the film forming apparatus 1 by, for example, a wired or wireless communication device.

### Example

In Example, first, a wafer W having a recess formed on a surface thereof was prepared. Subsequently, in the film forming apparatus 1, in a state where the wafer W is placed on the stage 3, a processing gas was supplied from the gas supplier 5 into the processing container 2, and RF power was supplied from the RF power supply 51 to the upper electrode to form a flowable film in the recess of the wafer W. A mixed gas including a halogen-containing silane, a halogen-free silane, and a diluent gas was used as the processing gas. Subsequently, the wafer W having the flowable film formed in the recess was transferred to another film forming apparatus 1 under a vacuum atmosphere. Subsequently, in that film forming apparatus 1, in a state where the wafer W was placed on the stage 3 in the processing container 2 under a H₂ gas atmosphere, the flowable film was cured to form a silicon film by thermally processing the wafer W at 550 degrees C. The thermal processing for the wafer W commenced 15 seconds after the completion of the formation of the flowable film on the wafer W.

The film formation conditions of the flowable film in Example are as follows.
halogen-containing silane: DCS (50 sccm)
halogen-free silane: SiH₄ (50 sccm)
diluent gas: H₂ (50 sccm), He (50 sccm)
pressure: 4 Torr (533 Pa)
RF Power: 13.56 MHz, 100 W
wafer temperature: 0 degrees C.
distance between electrodes: 15 mm

Next, the embedding characteristics of the silicon film embedded in the recess was observed with a scanning electron microscope (SEM). Further, the refractive index (RI) of the silicon film embedded in the recess was measured. As a result, it could be confirmed that the silicon film was formed in the recess by bottom-up growth. Further, the refractive index of the silicon film was 2.9.

From the results of the above example, it was found that, according to the method of forming a silicon-containing film of the embodiment, a silicon film may be formed in a recess by bottom-up growth.

The embodiments disclosed herein should be considered to be exemplary and not limitative in all respects. The above embodiments may be omitted, replaced or modified in various embodiments without departing from the scope of the appended claims and their gist.

In the above embodiment, a case where step S2 of forming the flowable film and step S3 of curing the flowable film are performed once in this order has been described, but the present disclosure is not limited to this. For example, step S2 of forming the flowable film and step S3 of curing the flowable film may be repeatedly performed.

In the above embodiment, a case where step S2 of forming the flowable film and step S3 of curing the flowable film are performed in different processing apparatuses connected to a vacuum transfer apparatus has been described, but the present disclosure is not limited to this. For example, step S2 of forming the flowable film and step S3 of curing the flowable film may be performed in the same processing apparatus. Further, for example, a processing apparatus having therein a first region for processing the substrate by heating it to a first temperature and a second region for processing the substrate by heating it to a second temperature may be used. In this case, since step S2 of forming the flowable film and step S3 of curing the flowable film may be performed in different regions within one processing apparatus, a transition time from the completion of step S2 of forming the flowable film to the initiation of step S3 of curing the flowable film may be shortened. Further, since the substrate on which the flowable film is formed may be proceeded to the step of curing the flowable film without unloading the substrate out of the processing apparatus, contamination of impurities may be particularly prevented.

This international application claims priority to Japanese Patent Application No. 2021-007404 filed on Jan. 20, 2021, which is incorporated herein by reference in its entirety.

### EXPLANATION OF REFERENCE NUMERALS

1: film forming apparatus W: wafer

1. A method for forming a silicon-containing film in a recess formed on a surface of a substrate, the method comprising:
(a) forming a flowable film in the recess by exposing the substrate, which is adjusted to a first temperature, to plasma generated from a processing gas including a halogen-containing silane; and
(b) curing the flowable film by thermally processing the substrate at a second temperature higher than the first temperature.

2. The method of claim 1, wherein the step (a) and the step (b) are continuously performed under a vacuum atmosphere.

3. The method of claim 2, wherein the halogen-containing silane is one or a plurality of gases represented by SiₙHₓZ₂ₙ₊₂₋ₓ (where Z is F, Cl, Br or I, n is a natural number of 1 or more, and x is 1 to 2n+2−1).

4. The method of claim 3, wherein the halogen-containing silane is at least one selected from a group consisting of SiHₓZ₄₋ₓ(where Z is F, Cl, Br or I, and x is 1, 2 or 3) and Si₂HₓZ₆₋ₓ (where Z is F, Cl, Br or I, and x is 1, 2, 3, 4 or 5).

5. The method of claim 4, wherein the halogen-containing silane is dichlorosilane (DCS).

6. The method of claim 5, wherein the processing gas includes a halogen-free silane.

7. The method of claim 6, wherein the halogen-free silane is one or a plurality of gases represented by SiₓH₂₊₂ₓ (where x is a natural number of 1 or more).

8. The method of claim 7, wherein the halogen-free silane is monosilane (SiH₄).

9. The method of claim 8, wherein the processing gas includes at least one of H₂, He, N₂ or Ar.

10. The method of claim 9, wherein the first temperature is 80 degrees C. or lower, and
wherein the second temperature is 150 degrees C. or higher and 750 degrees C. or lower.

11. The method of claim 10, wherein in the step (b), the substrate is exposed to plasma generated from H₂.

12. The method of claim 11, wherein in the step (b), the plasma is generated by RF power having a frequency band of 100 MHz or more and 1 GHz or less.

13. The method of claim 12, wherein in the step (b), the substrate is irradiated with ultraviolet rays.

14. The method of claim 13, wherein the processing gas includes a metal-containing gas.

15. The method of claim 14, wherein the metal-containing gas is trimethylaluminum (TMA).

16. The method of claim 15, wherein the step (b) is performed within 60 seconds after the step (a).

17. The method of claim 16, comprising repeating the step (a) and the step (b).

18. The method of claim 1, wherein the halogen-containing silane is one or a plurality of gases represented by SiₙHₓZ₂ₙ₊₂₋ₓ (where Z is F, Cl, Br or I, n is a natural number of 1 or more, and x is 1 to 2n+2−1).

19. The method of claim 1, wherein the halogen-containing silane is at least one selected from a group consisting of SiHₓZ₄₋ₓ (where Z is F, Cl, Br or I, and x is 1, 2 or 3) and Si₂HₓZ₆₋ₓ (where Z is F, Cl, Br or I, and x is 1, 2, 3, 4 or 5).

20. A film forming apparatus that forms a silicon-containing film in a recess formed on a surface of a substrate, the film forming apparatus comprising:
a film former configured to form a flowable film in the recess by exposing the substrate, which is adjusted to a first temperature, to plasma generated from a processing gas including a halogen-containing silane; and
a thermal processor configured to cure the flowable film by thermally processing the substrate at a second temperature higher than the first temperature.
